(19) United States
(12) Patent Application Publication
(10) Pub. No.: US 2024/0224696 A1
(43) Pub. Date: Jul. 4, 2024

(54) Display Device

(71) Applicant: LG Display Co., Ltd., Seoul (KR)

(72) Inventors: JaeMin Shim, Paju-si (KR); TaeHan Kim, Paju-si (KR); WooSang Kim, Paju-si (KR); Yoohwan Kim, Paju-si (KR); Seoil Jeon, Paju-si (KR)

(21) Appl. No.: 18/500,068

(22) Filed: Nov. 1, 2023

(30) Foreign Application Priority Data
Dec. 29, 2022 (KR) 10-2022-0189602

(51) Int. Cl. H10K 59/38; H10K 59/122; H10K 59/127; H10K 59/35; H10K 59/80

(52) U.S. Cl. CPC H10K 59/38; H10K 59/122; H10K 59/127; H10K 59/351; H10K 59/353; H10K 59/8792

(57) ABSTRACT

Disclosed is a display device comprising a first substrate including a non-transmission area having a plurality of subpixels, a second substrate confronting the first substrate, a plurality of color filters arranged to respectively correspond to the plurality of subpixels over the second substrate, and a black matrix disposed between each of the plurality of color filters over the second substrate, wherein each of the plurality of color filters is disposed to overlap the black matrix, and the plurality of color filters have different areas overlapped with the black matrix according to positions of corresponding subpixels.

### CROSS-REFERENCE TO RELATED APPLICATIONS

This application claims priority to Republic of Korea patent application no. 10-2022-0189602, filed Dec. 29, 2022, which is incorporated by reference herein in its entirety.

### BACKGROUND

### Technical Field

The present disclosure relates to a display device.

### Description of the Related art

With the advancement of the information age, the demand for a display device for displaying an image has increased in various forms. Therefore, various types of display devices such as a liquid crystal display (LCD) device, a plasma display panel (PDP) device, a quantum dot light emitting display (QLED) device and an organic light emitting display (OLED) device have been recently used.

In a display device, each subpixel can have a predetermined color while light emitted from a light emitting element passes through a color filter on an upper substrate. In this case, when a formation position of the color filter is moved due to a process error, it is difficult to realize a desired color in the display device due to color separation or color invasion between neighboring subpixels.

### SUMMARY

The present disclosure has been made in view of the above problems, and it is an object of the present disclosure to provide a display device capable of minimizing a color loss or color invasion between subpixels.

It is another object of the present disclosure to provide a display device having high light transmittance.

In accordance with an aspect of the present disclosure, the above and other objects can be accomplished by the provision of a display device comprising a first substrate including a non-transmission area having a plurality of subpixels, a second substrate confronting the first substrate, a plurality of color filters arranged to respectively correspond to the plurality of subpixels on the second substrate, and a black matrix disposed between each of the plurality of color filters on the second substrate, wherein each of the plurality of color filters is disposed to overlap the black matrix, and the plurality of color filters have different areas overlapped with the black matrix according to positions of corresponding subpixels.

In accordance with an aspect of the present disclosure, the display device comprises a first substrate and a second substrate which faces the first substrate, a first subpixel and a second subpixel, a first color filter and a second color filter, and a black matrix disposed around the first subpixel. The first color filter corresponding to the first subpixel receives light from the first subpixel and transmits light of a first color. The second color filter corresponding to the second subpixel receives light from the second subpixel and transmits light of a second color (e.g., white). A first portion of the black matrix is the region between the first subpixel and the second subpixel at a first side of the first color filter, and a second portion of the black matrix is at a second side opposite to the first side of the first color filter. The width of the second side of the first color filter overlapping the second portion of the black matrix is larger than a width of the first side of the first color filter overlapping the first portion of the black matrix. In this manner, color loss or color invasion between subpixels is reduced.

In addition to the effects of the present disclosure as mentioned above, additional advantages and features of the present disclosure will be clearly understood by those skilled in the art from the above description of the present disclosure.

### BRIEF DESCRIPTION OF DRAWINGS

The above and other objects, features and other advantages of the present disclosure will be more clearly understood from the following detailed description taken in conjunction with the accompanying drawings, in which:

FIG. 1 is a perspective view schematically illustrating a display device according to one embodiment of the present disclosure;

FIG. 2 is a plan view schematically illustrating a display panel according to one embodiment of the present disclosure;

FIG. 3 schematically illustrates one embodiment of a pixel provided in ‘A’ of FIG. 2, according to one embodiment of the present disclosure;

FIG. 4 is a cross sectional view along one example along I-I′ of FIG. 3, according to one embodiment of the present disclosure;

FIG. 5 is a cross sectional view along one example along II-II′ of FIG. 3, according to one embodiment of the present disclosure;

FIG. 6 is a cross sectional view along one example along III-III′ of FIG. 3, according to one embodiment of the present disclosure;

FIG. 7 is a cross sectional view along one example along IV-IV′ of FIG. 3, according to one embodiment of the present disclosure;

FIG. 8 illustrates a first color filter disposed adjacent to a white subpixel, according to one embodiment of the present disclosure;

FIG. 9 illustrates a fourth color filter disposed adjacent to a white subpixel, according to one embodiment of the present disclosure;

FIG. 10 illustrates a third color filter which is not adjacent to a white subpixel, according to one embodiment of the present disclosure; and

FIG. 11 is a cross sectional view illustrating a black matrix, a bank, and a planarization layer according to one embodiment of the present disclosure, and

FIG. 12 is a cross sectional view illustrating a comparative example.

### DETAILED DESCRIPTION OF THE DISCLOSURE

Advantages and features of the present disclosure, and implementation methods thereof will be clarified through following embodiments described with reference to the accompanying drawings. The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, dimensions (e.g., length, width, height, thickness, radius, diameter, area, etc.), a ratio, an angle, and a number of elements disclosed in the drawings for describing embodiments of the present disclosure are merely an example, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification. In the following description, when the detailed description of the relevant known function or configuration is determined to unnecessarily obscure the important point of the present disclosure, the detailed description will be omitted. In a situation where “comprise,” “have,” and “include” described in the present specification are used, another part can be added unless “only” is used. The terms of a singular form can include plural forms unless referred to the contrary.

In construing an element, the element is construed as including an error range although there is no explicit description.

In describing a position relationship, for example, when the position relationship is described as “upon˜,” “above˜,” “below,” and “next to,” one or more portions can be arranged between two other portions unless “just” or “direct” is used.

It will be understood that, although the terms “first,” “second,” etc., can be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first,” “second,” etc., can be used. These terms are intended to identify the corresponding elements from the other elements, and basis, order, or number of the corresponding elements are not limited by these terms. The expression that an element is “connected” or “coupled” to another element should be understood that the element can directly be connected or coupled to another element but can directly be connected or coupled to another element unless specially mentioned, or a third element can be interposed between the corresponding elements.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in co-dependent relationship and are combinable.

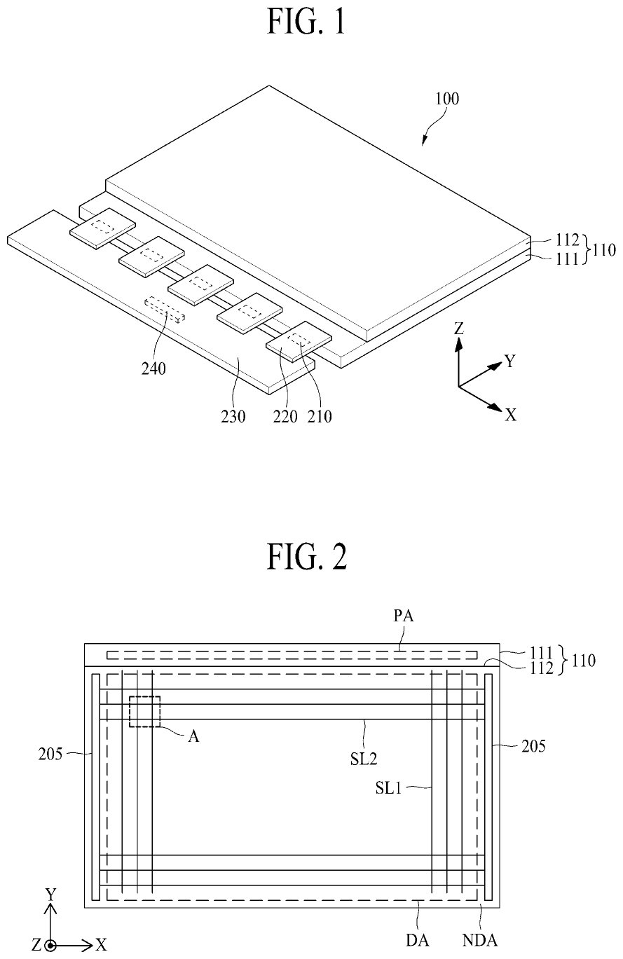

FIG. 1 is a plan view schematically illustrating a display device, according to one embodiment of the present disclosure. FIG. 2 is a schematic plan view illustrating a display panel, according to one embodiment of the present disclosure.

Hereinafter, X axis indicates a line parallel with a scan line, Y axis indicates a line parallel with a data line, and Z axis indicates a height direction of a display device 100.

Although a description has been described based on that the display device 100 according to one embodiment of the present disclosure is embodied as an organic light emitting display device, the transparent display device 100 can be embodied as a liquid crystal display device, a plasma display panel (PDP), a Quantum dot Light Emitting Display (QLED) or an Electrophoresis display device.

Referring to FIG. 1, a display device 100 according to one embodiment of the present disclosure includes a display panel 110, a source drive integrated circuit (hereinafter, referred to as “IC”) 210, a flexible film 220, a circuit board 230, and a timing controller 240.

The display panel 110 includes a first substrate 111 and a second substrate 112, which face each other. The second substrate 112 can be an encapsulation substrate. The first substrate 111 can be a plastic film, a glass substrate, or a silicon wafer substrate formed using a semiconductor process. The second substrate 112 may be a plastic film, a glass substrate, or an encapsulation film. The first substrate 111 and the second substrate 112 can be made of a transparent material.

The display panel 110 can include a display area DA where pixels are formed to display an image, and a non-display area NDA that does not display an image.

The display area DA can be provided with first signal lines SL1, second signal lines SL2 and the pixels. The non-display area NDA can be provided with a pad area PA in which pads are disposed, and at least one scan driver 205.

The first signal lines SL1 can be extended in a first direction (e.g., Y-axis direction). The first signal lines SL1 can cross the second signal lines SL2 in the display area DA. The second signal lines SL2 can be extended in the display area DA in a second direction (e.g., X-axis direction). The pixel can be provided in an area where at least one of the first signal line SL1 and the second signal line SL2 is provided, and emits predetermined light to display an image.

A plurality of pads can be disposed in the pad area PA. Since the size of the first substrate 111 is greater than that of the second substrate 112, a portion of the first substrate 111 can be exposed without being covered by the second substrate 112. Pads such as power pads and data pads can be provided over a portion of the first substrate 111 that is exposed and not covered by the second substrate 112.

The scan driver 205 are connected to the scan lines and supplies scan signals to the scan lines. The scan driver 205 can be disposed in the non-display area NDA on one side or both sides of the display area DA of the transparent display panel 110 by a gate driver in panel (GIP) method or a tape automated bonding (TAB) method.

The source drive IC 210 receives digital video data and source control signals from the timing controller 240. The source drive IC 210 converts the digital video data into analog data voltages in accordance with the source control signal, and supplies the analog data voltages to the data lines. If the source drive IC 210 is manufactured in a driving chip, the source drive IC 210 may be mounted on the flexible film 220 by a chip on film (COF) method or a chip on plastic (COP) method.

Lines connecting the pads with the source drive IC 210 and lines connecting the pads with lines of the circuit board 230 may be formed in the flexible film 220. The flexible film 220 can be attached onto the pads using an anisotropic conducting film, whereby the pads can be connected with the lines of the flexible film 220.

The circuit board 230 can be adhered to the flexible films 220. A plurality of circuits implemented as driving chips may be mounted on the circuit board 230. For example, the timing controller 240 can be mounted on the circuit board 230. The circuit board 230 can be a printed circuit board or a flexible printed circuit board.

The timing controller 240 receives digital video data and a timing signal from an external system board through a cable of the circuit board 230. The timing controller 240 generates a gate control signal for controlling an operation timing of the gate driving unit and a source control signal for controlling the source drive ICs 210 on the basis of the timing signal. The timing controller 240 supplies a gate control signal to the scan driver 205 and a source control signal to the source drive ICs 210.

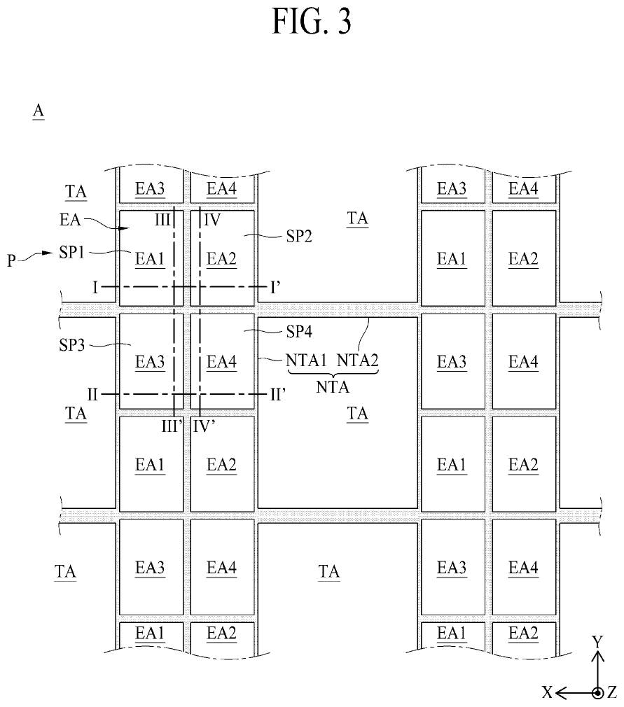

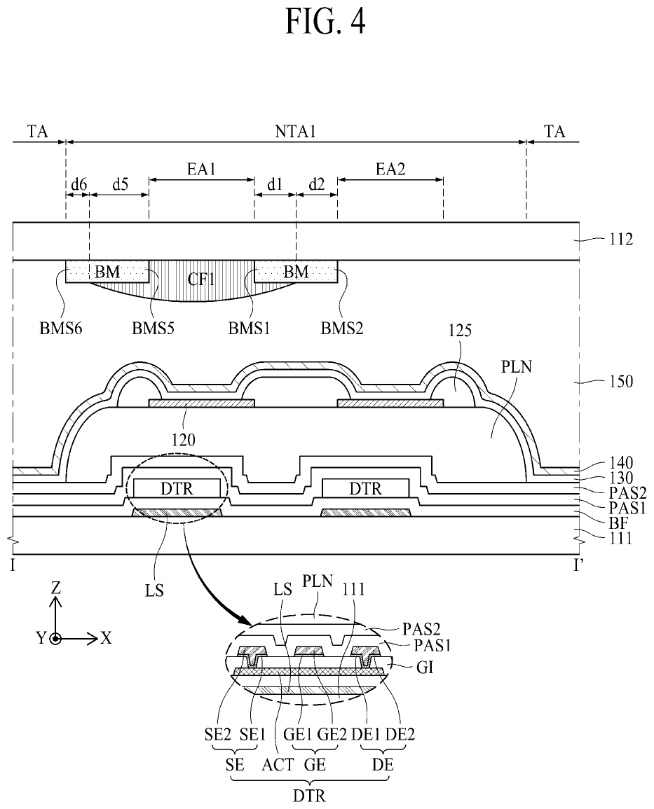

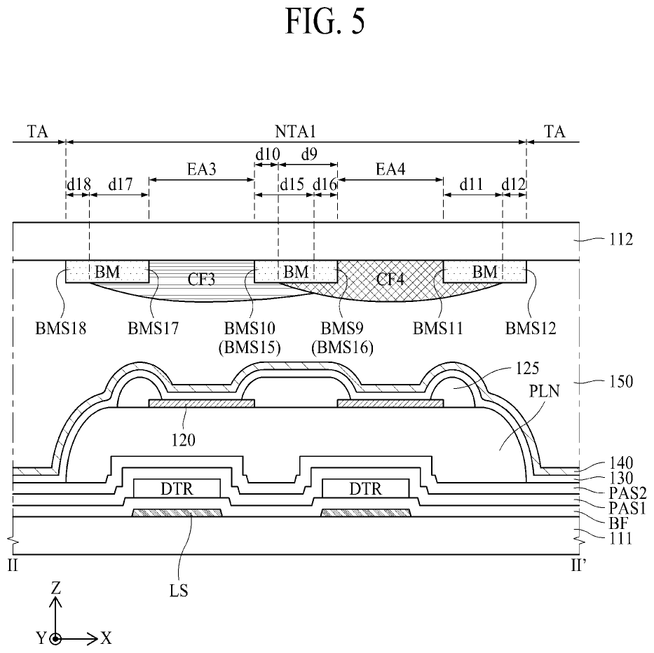

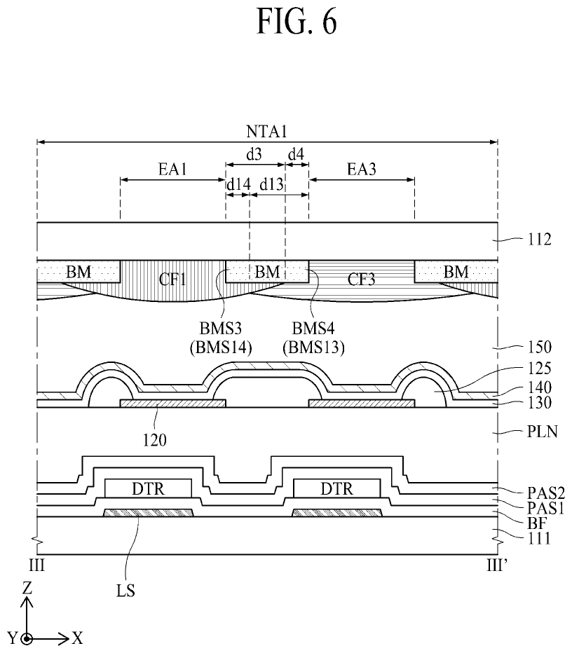

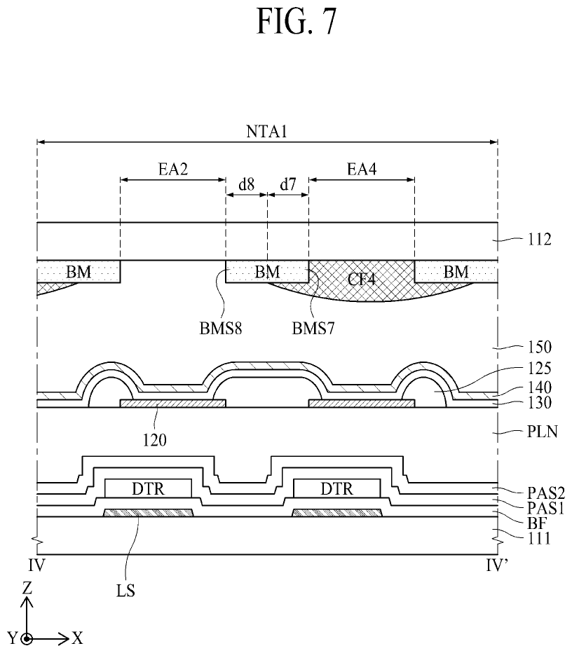

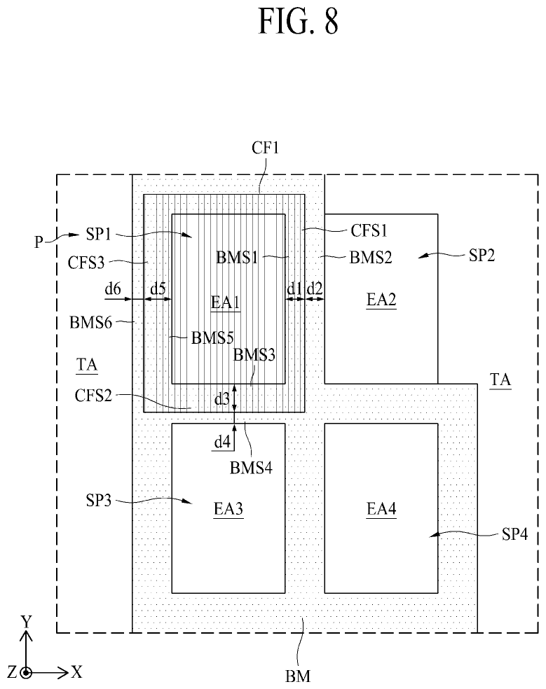

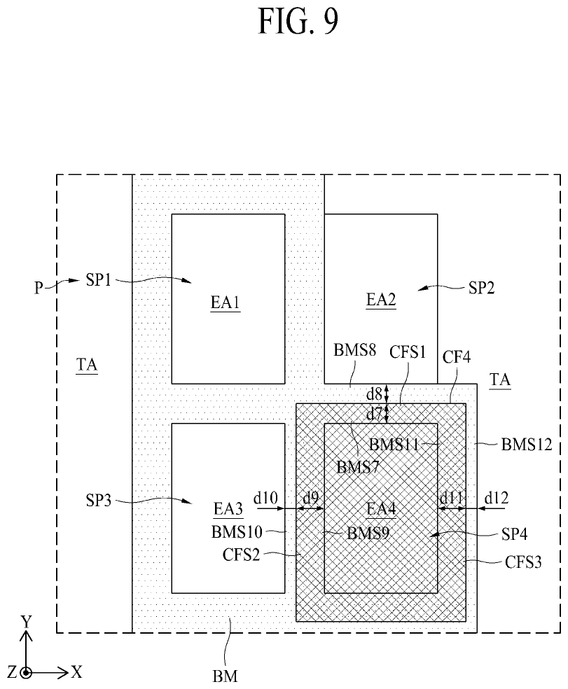

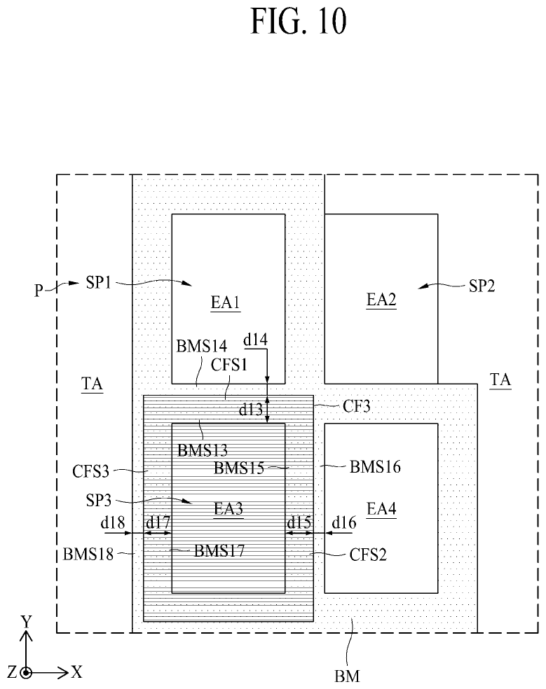

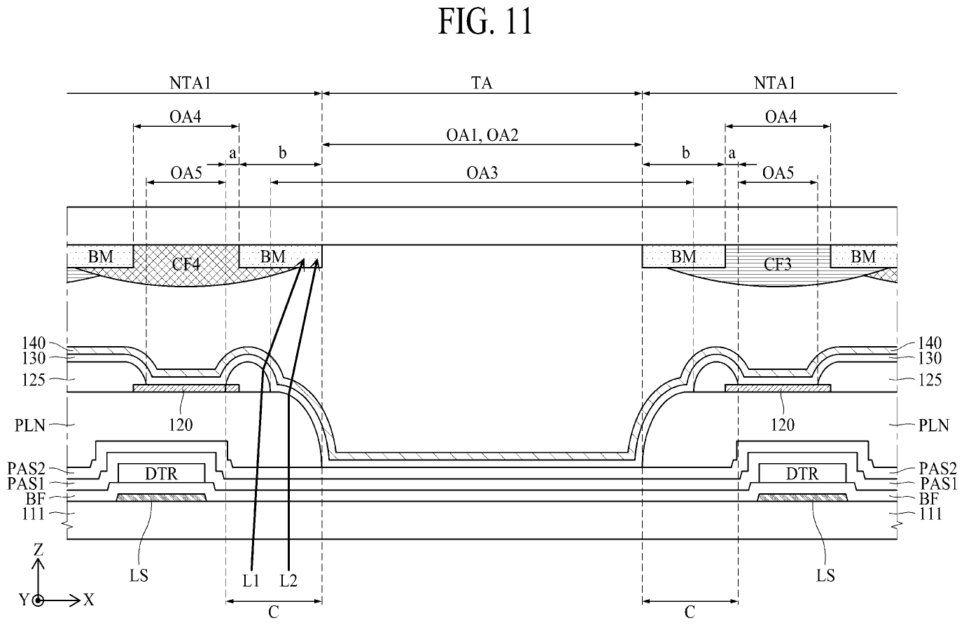

FIG. 3 schematically illustrates one embodiment of a pixel provided in ‘A’ of FIG. 2, according to one embodiment of the present disclosure. FIG. 4 is a cross sectional view along one example along I-I′ of FIG. 3, according to one embodiment of the present disclosure. FIG. 5 is a cross sectional view along one example along II-II′ of FIG. 3, according to one embodiment of the present disclosure. FIG. 6 is a cross sectional view along one example along III-III′ of FIG. 3, according to one embodiment of the present disclosure. FIG. 7 is a cross sectional view along one example along IV-IV′ of FIG. 3, according to one embodiment of the present disclosure. FIG. 8 illustrates a first color filter disposed adjacent to a white subpixel, according to one embodiment of the present disclosure. FIG. 9 illustrates a fourth color filter disposed adjacent to a white subpixel, according to one embodiment of the present disclosure. FIG. 10 illustrates a third color filter which is not adjacent to a white subpixel, according to one embodiment of the present disclosure.

The display area DA, as shown in FIG. 3, includes a transmissive area TA and a non-transmissive area NTA. The transmissive area TA is an area which allows most of the externally incident light to pass through, and the non-transmissive area NTA is an area through which most of the externally incident light fails to transmit through. For example, the transmissive area TA can be an area where light transmittance is greater than α %, and the non-transmissive area NTA can be an area where light transmittance is less than β %, where α is greater than β. A user can view an object or background arranged at a rear surface of the transparent display panel 110 (e.g., behind the display panel) due to the transmissive area TA.

The non-transmissive area NTA can include a first non-transmissive area NTA1, a second non-transmissive area NTA2 and a plurality of pixels P.

The first non-transmissive area NTA1 can be extended in a first direction (e.g., Y-axis direction) in a display area DA, and can be disposed to at least partially overlap light emission areas EA1, EA2, EA3 and EA4. A plurality of first non-transmissive areas NTA1 can be provided in the transparent display panel 110, and the transmissive area TA can be provided between two adjacent first non-transmissive areas NTA1. In the first non-transmissive area NTA1, first signals lines SL1 extended in the first direction (e.g., Y-axis direction) can be disposed to be spaced apart from each other.

For example, the first signal lines SL1 can include at least one of a pixel power line, a common power line, a reference line and data lines.

The pixel power line can supply a first power source to a driving transistor DTR of each of subpixels SP1, SP2, SP3 and SP4 provided in the display area DA. The common power line can supply a second power source to a cathode electrode of the subpixels SP1, SP2, SP3 and SP4 provided in the display area DA. At this time, the second power source can be a common power source commonly supplied to the subpixels SP1, SP2, SP3 and SP4.

The reference line RL can supply an initialization voltage (or sensing voltage) to the driving transistor DTR of each of the subpixels SP1, SP2, SP3 and SP4 provided in the display area DA. Each of the data lines DL can supply a data voltage to the subpixels SP1, SP2, SP3 and SP4.

The transparent display panel 110 according to one embodiment of the present disclosure is provided with a pixel P between adjacent transmissive areas TA. The pixel P can include light emission areas EA1, EA2, EA3 and EA4 in which a light emitting element is disposed to emit light. Since the non-transmissive area NTA in the transparent display panel 110 has a small area, a circuit element can be disposed to at least partially overlap with the light emission areas EA1, EA2, EA3 and EA4.

The second non-transmissive area NTA2 can be extended in the display area DA in a second direction (e.g., X-axis direction), and can be disposed to at least partially overlap the light emission areas EA1, EA2, EA3 and EA4. A plurality of second non-transmissive areas NTA2 can be provided in the transparent display panel 110, and the transmissive area TA can be provided between two adjacent second non-transmissive areas NTA2. The second signal line SL2 can be disposed in the second non-transmissive area NTA2.

The second signal line SL2 is extended in a second direction (e.g., X-axis direction), and can include, for example, a scan line SCANL. The scan line SCANL can supply a scan signal to subpixels SP1, SP2, SP3 and SP4 of the pixel P.

Pixels P can be provided to at least partially overlap with at least one of the first signal line SL1 and the second signal line SL2, thereby emitting predetermined light to display an image. A light emission area EA can correspond to an area, from which light is emitted, in the pixel P.

Each of the pixels P, as shown in FIG. 3, can include at least one of a first subpixel SP1, a second subpixel SP2, a third subpixel SP3 and a fourth subpixel SP4. The first subpixel SP1 can include a first light emission area EA1 emitting light of a first color. The second subpixel SP2 can include a second light emission area EA2 emitting light of a second color. The third subpixel SP3 can include a third light emission area EA3 emitting light of a third color. The fourth subpixel SP4 can include a fourth light emission area EA4 emitting light of a fourth color.

The first to fourth light emission area EA1, EA2, EA3 and EA4 can emit light of different colors. For example, the first light emission area EA1 can emit light of a green color. The second light emission area EA2 can emit light of a white color. The third light emission area EA3 can emit light of a blue color. The fourth light emission area EA4 can emit light of a red color. However, the light emission areas are not limited to this example. Also, the arrangement order of the subpixels SP1, SP2, SP3 and SP4 can be changed in various ways.

Each of the first subpixel SP1, the second subpixel SP2, the third subpixel SP3 and the fourth subpixel SP4 can include at least one transistor and a capacitor.

The at least one transistor can include a driving transistor DTR and switching transistors. The switching transistor can be switched according to a scan signal supplied to the scan line and can be configured to charge the capacitor with a data voltage supplied from the data line.

The driving transistor DTR can be switched in accordance with the data voltage charged in the capacitor to generate a data current from a power source supplied from the pixel power line and supply the data current to a first electrode 120 of subpixels SP1, SP2, SP3 and SP4. The driving transistor DTR can include an active layer ACT, a gate electrode GE, a source electrode SE and a drain electrode DE.

In detail, as shown in FIG. 4, a light-shielding layer LS can be provided over the first substrate 111. The light-shielding layer LS can serve to shield external light incident on the active layer ACT in an area where the driving transistor DTR is formed (e.g., preventing the active layer from being damaged). The light-shielding layer LS can include a single layer or multi-layer made of any one of molybdenum (Mo), aluminum (Al), chromium (Cr), gold (Au), titanium (Ti), nickel (Ni), neodymium (Nd) and copper (Cu) or their alloy.

A buffer layer BF can be provided over the light-shielding layer LS. The buffer layer BF is intended to protect the driving transistor DTR from moisture permeated through the first substrate 111 vulnerable to moisture permeation, and can include an inorganic layer, for example, a silicon oxide layer (SiOx), a silicon nitride layer (SiNx) or their multi-layer.

An active layer ACT of the driving transistor DTR can be provided over the buffer layer BF. The active layer ACT can be formed of a silicon-based semiconductor material or an oxide-based semiconductor material.

A gate insulating layer GI can be provided over the active layer ACT of the driving transistor DTR. The gate insulating layer GI can be patterned only in an area where the gate electrode GE is disposed. The gate insulating layer GI can include an inorganic layer, for example, a silicon oxide layer (SiOx), a silicon nitride layer (SiNx) or their multi-layer.

The gate electrode GE, the source electrode SE and the drain electrode DE of the driving transistor DTR can be provided over the gate insulating layer GI. The driving transistor DTR can include a channel area in which the active layer ACT and the gate electrode GE overlap, and a source area and a drain area with the channel area interposed therebetween. At this time, the active layer ACT provided in the source area of the driving transistor DTR can be connected to the source electrode SE of the driving transistor DTR. The active layer ACT provided in the drain area of the driving transistor DTR can be connected to the drain electrode DE of the driving transistor DTR.

The gate electrode GE, the source electrode SE and the drain electrode DE of the driving transistor DTR can be formed of the same material on the same layer as shown in FIG. 4, but are not necessarily limited thereto. In another embodiment, the source electrode SE and the drain electrode DE of the driving transistor DTR can be formed of a different material on a layer different from that of the gate electrode GE.

The gate electrode GE, the source electrode SE and the drain electrode DE can include a single layer or multi-layer made of any one of molybdenum (Mo), aluminum (Al), chromium (Cr), gold (Au), titanium (Ti), nickel (Ni), neodymium (Nd) and copper (Cu) or their alloy.

In one embodiment, the gate electrode GE may be formed of a double layer including a first gate electrode GE1 and a second gate electrode GE2 as shown in FIG. 4. The first gate electrode GE1 may be provided between the gate insulating layer GI and the second gate electrode GE2 to improve adhesion between the gate insulating layer GI and the second gate electrode GE2. In addition, the first gate electrode GE1 protects the lower surface of the second gate electrode GE2 to prevent the second gate electrode GE2 from being corroded. The first gate electrode GE1 may include a material having a lower oxidation degree than the second gate electrode GE2. For example, the first gate electrode GE1 may include an alloy (MoTi) of molybdenum (Mo) and titanium (Ti), but is not necessarily limited thereto.

The second gate electrode GE2 may be provided over the first gate electrode GE1. The second gate electrode GE2 may include a metal having lower resistance than the first gate electrode GE1. For example, the second gate electrode GE2 may include copper (Cu), which is a low resistance metal, but is not necessarily limited thereto. The second gate electrode GE2 may be formed thicker than the first gate electrode GE2 to reduce the total resistance.

In one embodiment, the source electrode SE may be formed of a double layer including a first source electrode SE1 and a second source electrode SE2 as shown in FIG. 4. The first source electrode SE1 may be provided between the gate insulating layer GI and the second source electrode SE2 to improve adhesion between the gate insulating layer GI and the second source electrode SE2. In addition, the first source electrode SE1 protects the lower surface of the second source electrode SE2 to prevent the second source electrode SE2 from being corroded. The first source electrode SE1 may include a material having a lower oxidation degree than the second source electrode SE2. For example, the first source electrode SE1 may include an alloy (MoTi) of molybdenum (Mo) and titanium (Ti), but is not necessarily limited thereto.

The second source electrode SE2 may be provided over the first source electrode SE1. The second source electrode SE2 may include a metal having lower resistance than the first source electrode SE1. For example, the second source electrode SE2 may include copper (Cu), which is a low resistance metal, but is not necessarily limited thereto. The second source electrode SE2 may be formed thicker than the first source electrode SE2 to reduce the total resistance.

In one embodiment, the drain electrode DE may be formed of a double layer including a first drain electrode DE1 and a second drain electrode DE2 as shown in FIG. 4. The first drain electrode DE1 may be provided between the gate insulating layer GI and the second drain electrode DE2 to improve adhesion between the gate insulating layer GI and the second drain electrode DE2. In addition, the first drain electrode DE1 protects the lower surface of the second drain electrode DE2 to prevent the second drain electrode DE2 from being corroded. The first drain electrode DE1 may include a material having a lower oxidation degree than the second drain electrode DE2. For example, the first drain electrode DE1 may include an alloy (MoTi) of molybdenum (Mo) and titanium (Ti), but is not necessarily limited thereto.

The second drain electrode DE2 may be provided over the first drain electrode DE1. The second drain electrode DE2 may include a metal having lower resistance than the first drain electrode DE1. For example, the second drain electrode DE2 may include copper (Cu), which is a low resistance metal, but is not necessarily limited thereto. The second drain electrode DE2 may be formed thicker than the first drain electrode DE2 to reduce the total resistance.

A first insulating layer PAS1 for insulating the driving transistor DTR can be provided over the gate electrode GE, the source electrode SE and the drain electrode DE of the driving transistor DTR, and a second insulating layer PAS2 can be provided over the first insulating layer PAS1. The first and second insulating layers PAS1 and PAS2 can include an inorganic layer, for example, a silicon oxide layer (SiOx), a silicon nitride layer (SiNx) or their multi-layer. A separate metal layer can be provided between the first and second insulating layers PAS1 and PAS2.

A planarization layer PLN for planarizing the step difference caused by the driving transistor DTR and signal lines can be provided over the first and the second insulating layer PAS2. The planarization layer PLN can be provided in the non-transmission area NTA and may not be provided in at least a portion of the transmission area TA. The planarization layer PLN can include open area overlapping at least a portion of the transmission area TA. The planarization layer PLN can induce refraction of light being transmitted therethrough, to thereby suppress transparency. Therefore, the transparent display panel 110 according to one embodiment of the present disclosure can increase transparency by removing a portion of the planarization layer PLN in the transmission area TA (e.g., there can be fewer layers in the transmission area TA).

The planarization layer PLN can include an organic film such as acryl resin, epoxy resin, phenolic resin, polyamide resin, or polyimide resin.

A light emitting element, which includes a first electrode 120, an organic light emitting layer 130 and a second electrode 140, and a bank 125 can be provided over the planarization layer PLN.

The first electrode 120 can be provided over the planarization layer PLN for each of the subpixels SP1, SP2, SP3 and SP4. The first electrode 120 can not provided in the transmissive area TA. The first electrode 120 can be connected to the driving transistor DTR. In detail, the first electrode 120 can be connected to one of the source electrode SE and the drain electrode DE of the driving transistor DTR through a contact hole that passes through the planarization layer PLN and the first and second insulating layers PAS1 and PAS2.

The first electrode 120 can include a metal material having high reflectance, such as a stacked structure (Ti/Al/Ti) of aluminum and titanium, a stacked structure (ITO/Al/ITO) of aluminum and ITO, an Ag alloy, a stacked structure (ITO/Ag alloy/ITO) of Ag alloy and ITO, a MoTi alloy, and a stacked structure (ITO/MoTi alloy/ITO) of MoTi alloy and ITO. The Ag alloy can be an alloy of silver (Ag), palladium (Pd), copper (Cu), etc. The MoTi alloy can be an alloy of molybdenum (Mo) and titanium (Ti). The first electrode 120 can be an anode electrode.

The bank 125 can be provided over the planarization layer PLN. The bank 125 can be provided to at least partially cover an edge of the first electrode 120 and expose a portion of the first electrode 120. Therefore, the bank 125 can prevent a problem in which light emitting efficiency is deteriorated due to concentration of a current on an end of the first electrode 120.

The bank 125 can define light emission areas EA1, EA2, EA3 and EA4 of the subpixels SP1, SP2, SP3 and SP4. The light emission areas EA1, EA2, EA3 and EA4 of each of the subpixels SP1, SP2, SP3 and SP4 represent an area in which the first electrode 120, the organic light emitting layer 130 and the second electrode 140 are sequentially stacked and holes from the first electrode 120 and electrons from the second electrode 140 are combined with each other in the organic light emitting layer 130 to emit light. In this situation, the area in which the bank 125 is provided can become the non-light emission area because light is not emitted therefrom, and the area in which the bank 125 is not provided and the first electrode is exposed can become the light emission area EA.

The bank 125 can include an organic layer such as an acrylic resin, an epoxy resin, a phenolic resin, a polyamide resin, and a polyimide resin.

The organic light emitting layer 130 can be disposed over the first electrode 120. The organic light emitting layer 130 can include a hole transporting layer, a light emitting layer and an electron transporting layer. In this situation, when a voltage is applied to the first electrode 120 and the second electrode 140, holes and electrons move to the light emitting layer through the hole transporting layer and the electron transporting layer, respectively and are combined with each other in the light emitting layer to emit light.

In one embodiment, the organic light emitting layer 130 can be a common layer commonly provided in the subpixels SP1, SP2, SP3 and SP4. In this situation, the light emitting layer can be a white light emitting layer for emitting white light.

In another embodiment, the light emitting layer of the organic light emitting layer 130 can be separately provided for each of the subpixels SP1, SP2, SP3 and SP4. For example, a green light emitting layer for emitting green light can be provided in the first subpixel SP1, a white light emitting layer for emitting white light can be provided in the second subpixel SP2, a blue light emitting layer for emitting blue light can be provided in the third subpixel SP3, and a red light emitting layer for emitting red light can be provided in the fourth subpixel SP4. In this situation, the light emitting layer of the organic light emitting layer 130 is not provided in the transmissive area TA.

A second electrode 140 can be disposed over the organic light emitting layer 130 and the bank 125. The second electrode 140 can be provided in the non-transmissive area NTA and the transmissive area TA.

The second electrode 140 can be a common layer commonly formed on the subpixels SP1, SP2, SP3, and SP4 to apply the same voltage. A second electrode 140 can include a transparent conductive material TCO such as ITO and IZO, or a semi-transmissive conductive material such as magnesium Mg, silver Ag, or an alloy of magnesium Mg and silver Ag. When the second electrode 140 includes a semi-transmissive metal material, a light emission efficiency can be increased by a micro cavity. The second electrode 140 can be an cathode electrode.

An encapsulation layer 150 can be provided over the light emitting elements The encapsulation layer 150 can be provided over the second electrode 140 and can be configured to cover the second electrode 140. The encapsulation layer 150 prevents oxygen or moisture from penetrating into an organic light emitting layer 130, the second electrode 140. To this end, the encapsulation layer 150 can include at least one inorganic layer and at least one organic film.

Meanwhile, although not shown in FIG. 4 and FIG. 7, a capping layer can additionally be provided between the second electrode 140 and the encapsulation layer 150.

A color filter CF can be provided over an encapsulation layer 150. The color filter can be provided over one surface of a second substrate 112 confronting a first substrate 111. In this case, the first substrate 111 having the encapsulation layer 150 and the second substrate 112 having the color filter can be bonded to each other by a separate adhesive layer (not shown). In this case, the adhesive layer (not shown) can be an optically clear resin layer OCR or an optically clear adhesive film OCA.

The color filter can be patterned for each of subpixels SP1, SP2, SP3, and SP4. In detail, the color filter can include a first color filter CF1, a second color filter, a third color filter CF3, and a fourth color filter CF4. The first color filter CF1 can be disposed to correspond to an emission area EA1 of the first subpixel SP1, for example, a green color filter which transmits green light. The second color filter can be disposed to correspond to an emission area EA2 of the second subpixel SP2, for example, a white color filter which transmits white light. The white color filter can be formed of a transparent organic material which transmits white light, but not necessarily limited thereto. The second color filter can be omitted as shown in FIGS. 4 and 7. The third color filter CF3 can be disposed to correspond to an emission area EA3 of the third subpixel SP3, for example, a blue color filter which transmits blue light. The fourth color filter CF4 can be disposed to correspond to an emission area EA4 of the fourth subpixel SP4, for example, a red color filter which transmits red light.

A black matrix BM can be provided between each of the color filters CF1, CF3, and CF4 and between the color filter CF1, CF3, and CF 4 and a transmission area TA. The black matrix BM is provided between each of the subpixels SP1, SP2, SP3, and SP4, so that it is possible to prevent color mixture from occurring between the adjacent subpixels SP1, SP2, SP3, and SP4, and to prevent light incident from the outside from being reflected to a plurality of signal lines provided between the subpixels SP1, SP2, SP3, and SP4, for example, scan lines, data lines, pixel power lines, common power lines, reference lines, and the like.

Also, the black matrix BM is provided between the transmission area TA and the plurality of subpixels SP1, SP2, SP3, and SP4, thereby preventing light emitted from each of the plurality of subpixels SP1, SP2, SP3, and SP4 from proceeding to the transmission area TA. According to one embodiment of the present disclosure, the black matrix BM cannot be provided between the white subpixel and the transmission area TA. A display panel 110 according to one embodiment of the present disclosure does not include the black matrix BM between the white subpixel and the transmission area TA, thereby reducing a formation area of the black matrix BM. Accordingly, the display panel 110 according to one embodiment of the present disclosure can improve a transmittance.

The black matrix BM can include a light absorbing material, for example, a black dye which absorbs light in a visible wavelength band.

The display panel 110 according to one embodiment of the present disclosure is characterized in that the plurality of color filters have different areas overlapped with the black matrix BM according to the position.

The plurality of subpixels SP1, SP2, SP3, and SP4 can be divided into the subpixel disposed adjacent to the white subpixel and the subpixel disposed not to be adjacent to the white subpixel. Hereinafter, for convenience of description, it is assumed that the second subpixel SP2 is the white subpixel. In this case, the first subpixel SP1 and the fourth subpixel SP4 correspond to the subpixels disposed adjacent to the white subpixel, and the third subpixel SP3 can correspond to the subpixel disposed not to be adjacent to the white subpixel, but not limited thereto. The subpixel disposed adjacent to the white subpixel and the subpixel disposed not to be adjacent to the white subpixel can vary according to the arrangement position and arrangement order of the subpixels.

In case of the first color filter CF1 and the fourth color filter CF4 respectively corresponding to the first subpixel SP1 and the fourth subpixel SP4, its area overlapped with the black matrix BM can be different from that of the third color filter CF3 corresponding to the third subpixel SP3.

More specifically, as shown in FIG. 8, the first color filter CF1 can include a first side CFS1 facing the white subpixel SP2 and a second side CFS2 facing the third subpixel SP3 disposed not to be adjacent to the white subpixel SP2. The first color filter CF1 can overlap at least a first portion of the black matrix BM at the first side CFS1 and the second side CFS2.

In case of the first color filter CF1, the area overlapped with the first portion of the black matrix BM can be differently provided in the first side CFS1 and the second side CFS2. The area between the first color filter CF1 and the first portion of the black matrix BM in the first side CFS1 can be a first area, and the area between the first color filter CF1 and the black matrix BM in the second side CFS2 can be a second area which is larger than the first area.

Also, in case of the first color filter CF1, a width of the area overlapped with the first portion of the black matrix BM can be differently provided in the first side CFS1 and the second side CFS2. The width of the area between the first color filter CF1 and the first portion of the black matrix BM in the first side CFS1 can be a first width, and the width of the area between the first color filter CF1 and the black matrix BM in the second side CFS2 can be a second width which is larger than the first width. Therefore, in one embodiment, a width of the second side CFS2 of the first color filter CF1 overlapping a second portion of the black matrix BM opposite the first side CFS1 of the first color filter CF1 may be larger than a width of the first side CFS1 of the first color filter CF1 overlapping a first portion of the black matrix BM in a region between the first subpixel and the second subpixel.

The black matrix BM provided in the region between the first subpixel SP1 and the white subpixel SP2 can include a first portion of a black matrix BM. The first side BMS1 is adjacent to the first subpixel SP1 and a second side BMS2 is adjacent to the white subpixel SP2. A distance between an end of the first side BMS1 of the black matrix BM and an end of the first side CFS1 of the first color filter CF1 can be a first distance d1. A distance between an end of the second side BMS2 of the black matrix BM and an end of the first side CFS1 of the first color filter CF1 can be a second distance d2. The first distance d1 can be equal to or less than the second distance d2. In one embodiment of the present disclosure, the first distance d1 and the second distance d2 can have a ratio of 1:1. That is, the end of the first color filter CF1 in the first side CFS1 can be disposed in the center of the black matrix BM.

The black matrix BM provided between the first subpixel SP1 and the third subpixel SP3 can include a third side BMS3 adjacent to the first subpixel SP1 and a fourth side BMS4 adjacent to the third subpixel SP3. A distance between an end of the third side BMS3 of the black matrix BM and an end of the second side CFS2 of the first color filter CF1 can be a third distance d3. A distance between an end of the fourth side BMS4 of the black matrix BM and an end of the second side CFS2 of the first color filter CF1 can be a fourth distance d4. The third distance d3 can be greater than the fourth distance d4. That is, the end of the first color filter CF1 in the second side CFS2 can be disposed closer to the third subpixel SP3 than the first subpixel SP1. In one embodiment of the present disclosure, the third distance d3 and the fourth distance d4 can have a ratio of 5:2.

As shown in FIG. 9, the fourth color filter CF4 can include a first side CFS1 facing the white subpixel SP2 and a second side CFS2 configured to face the third subpixel SP3 and disposed not to be adjacent to the white subpixel SP2. The fourth color filter CF4 can overlap at least a portion of the black matrix BM at the first side CFS1 and the second side CFS2.

In case of the fourth color filter CF4, the area overlapped with the black matrix BM can be differently provided in the first side CFS1 and the second side CFS2. The area between the fourth color filter CF4 and the black matrix BM in the first side CFS1 can be a third area, and the area between the fourth color filter CF4 and the black matrix BM in the second side CFS2 can be a fourth area which is larger than the third area.

The black matrix BM provided between the fourth subpixel SP4 and the white subpixel SP2 can include a seventh side BMS7 adjacent to the fourth subpixel SP4 and an eighth side BMS8 adjacent to the white subpixel SP2. A distance between an end of the seventh side BMS7 of the black matrix BM and an end of the first side CFS1 of the fourth color filter CF4 can be a seventh distance d7. A distance between an end of the eighth side BMS8 of the black matrix BM and an end of the first side CFS1 of the fourth color filter CF4 can be an eighth distance d8.

The seventh distance d7 can be equal to or less than the eighth distance d8. The seventh distance d7 can be equal to the first distance d1, but not necessarily. The seventh distance d7 can be different from the first distance d1. Also, the eighth distance d8 can be equal to the second distance d2, but not necessarily. The eighth distance d8 can be different from the second distance d2. In one embodiment of the present disclosure, the seventh distance d7 and the eighth distance d8 can have a ratio of 1:1. That is, the end of the fourth color filter CF4 in the first side CFS1 can be disposed in the center of the black matrix BM.

The black matrix BM provided between the fourth subpixel SP4 and the third subpixel SP3 can include a ninth side BMS9 adjacent to the fourth subpixel SP4 and a tenth side BMS10 adjacent to the third subpixel SP3. A distance between an end of the ninth side BMS9 of the black matrix BM and an end of the second side CFS2 of the fourth color filter CF4 can be a ninth distance d9. A distance between an end of the tenth side BMS10 of the black matrix BM and an end of the second side CFS2 of the fourth color filter CF4 can be a tenth distance d10.

The ninth distance d9 can be greater than the tenth distance d10. That is, the end of the fourth color filter CF4 in the second side CFS2 can be disposed closer to the third subpixel SP3 than the fourth subpixel SP4. In this case, the ninth distance d9 can be equal to the third distance d3, but not necessarily. The ninth distance d9 can be different from the third distance d3. The tenth distance d10 can be equal to the fourth distance d4, but not necessarily. The tenth distance d10 can be different from the fourth distance d4. In one embodiment of the present disclosure, the ninth distance d9 and the tenth distance d10 can have a ratio of 5:2.

The display panel 110 according to one embodiment of the present disclosure can be designed in that the overlap area between the black matrix BM and each of the first color filter CF1 and the fourth color filter CF4 can be relatively small in the side adjacent to the white subpixel SP2.

The color filters CF1, CF3, and CF4 overlap the black matrix BM, but can be designed not to overlap the neighboring subpixel. However, the color filters CF1, CF3, and CF4 can be provided to overlap the neighboring subpixel due to a process error when the color filters CF1, CF3, and CF4 are provided over the second substrate 112. In this case, the neighboring subpixel can generate light of an undesired color due to color invasion. Particularly, when the color invasion occurs, the white subpixel SP2 has high visibility, whereby it can be easily recognized by a viewer.

According to one embodiment of the present disclosure, the area of the first color filter CF1 and the fourth color filter CF4 is reduced in the side adjacent to the white subpixel SP2 over the display panel 110, thereby preventing the first color filter CF1 and the fourth color filter CF4 from invading the white subpixel SP2 even when a process error occurs.

Meanwhile, the display panel 110 according to one embodiment of the present disclosure can be designed in that the overlap area between the black matrix BM and each of the first color filter CF1 and the fourth color filter CF4 can be relatively large in the side adjacent to another subpixel instead of the white subpixel SP2.

The color filters CF1, CF3, and CF4 can be provided to have the larger size than the emission area EA. Thus, the color filters CF1, CF3, and CF4 overlap at least a portion of the black matrix BM, and the color filters CF1, CF3, and CF4 can be provided to cover the emission area EA even when a fine error occurs in the process. However, when the process error is increased, the color filters CF1, CF3, and CF4 cannot be provided in the entire area of the emission area EA, whereby a color loss can occur.

The display panel 110 according to one embodiment of the present disclosure is designed in that the area of the first color filter CF1 and the area of the fourth color filter CF4 are relatively large in the side adjacent to another subpixel instead of the white subpixel SP2. Thus, even though the process error occurs, the first color filter CF1 can be provided over the entire first emission area EA1, and the fourth color filter CF4 can be provided in the entire fourth emission area EA4. Accordingly, the display panel 110 according to one embodiment of the present disclosure can prevent the color loss from occurring in the first subpixel SP1 and the fourth subpixel SP4.

Also, the display panel 110 according to one embodiment of the present disclosure can be designed in that the overlap area between the black matrix BM and each of the first color filter CF1 and the fourth color filter CF4 can be relatively large in the side adjacent to the transmission area TA.

As shown in FIG. 8, the first color filter CF1 can further include a third side CFS3 facing the transmission area TA. The black matrix BM provided in the region between the first subpixel SP1 and the transmission area TA can include a second portion of the black matrix BM which is at an opposite side to the first portion of the black matrix. The fifth side BMS5 is adjacent to the first subpixel SP1 and a sixth side BMS6 is adjacent to the transmission area TA. A distance between an end of the fifth side BMS5 of the black matrix BM, at the second portion of the black matrix BM, and an end of the third side CFS3 of the first color filter CF1 can be a fifth distance d5. A distance between an end of the sixth side BMS6 of the black matrix BM, at the second portion of the black matrix BM, and an end of the third side CFS3 of the first color filter CF1 can be a sixth distance d6.

The fifth distance d5 can be greater than the sixth distance d6. In one embodiment of the present disclosure, the fifth distance d5 and the sixth distance d6 can have a ratio of 5:2.

As shown in FIG. 9, the fourth color filter CF4 can further include a third side CFS3 facing the transmission area TA. The black matrix BM provided between the fourth subpixel SP4 and the transmission area TA can include an eleventh side BMS11 adjacent to the fourth subpixel SP4 and a twelfth side BMS12 adjacent to the transmission area TA. A distance between an end of the eleventh side BMS11 of the black matrix BM and an end of the third side CFS3 of the fourth color filter CF4 can be an eleventh distance d11. A distance between an end of the twelfth side BMS12 of the black matrix BM and an end of the third side CFS3 of the fourth color filter CF4 can be a twelfth distance d12.

The eleventh distance d11 can be greater than the twelfth distance d12. The eleventh distance d11 can be equal to the fifth distance d5, but not necessarily. The eleventh distance d11 can be different from the fifth distance d5. In addition, the twelfth distance d12 can be equal to the sixth distance d6, but not necessarily. The twelfth distance D12 can be different from the fifth distance d5. In one embodiment of the present disclosure, the eleventh distance d11 and the twelfth distance d12 can have a ratio of 5:2.

The display panel 110 according to one embodiment of the present disclosure is designed in that the area of the first color filter CF1 and the area of the fourth color filter CF4 are relatively large in the side adjacent to the transmission area TA. Thus, even though the process error occurs, the first color filter CF1 can be provided over the entire first emission area EA1, and the fourth color filter CF4 can be provided in the entire fourth emission area EA4. Accordingly, the display panel 110 according to one embodiment of the present disclosure can prevent the color loss from occurring in the first subpixel SP1 and the fourth subpixel SP4.

In the display panel 110 according to one embodiment of the present disclosure, as compared to the overlap area between the black matrix BM and each of the first color filter CF1 and the fourth color filter CF4, the overlap area between the black matrix BM and the third color filter CF3 can be differently provided.

More specifically, as shown in FIG. 10, the third color filter CF3 can include a first side CFS1 facing the first subpixel SP1 and a second side CFS2 facing the fourth subpixel SP4. The third color filter CF3 can overlap at least a portion of the black matrix BM in the first side CFS1 and the second side CFS2. Also, the third color filter CF3 can at least partially overlap the first color filter CF1 in the first side CFS1 and can at least partially overlap the fourth color filter CF4 in the second side CFS2. Therefore, in one embodiment, a first side CFS1 of a third color filter CF3 may overlap a third portion of the black matrix BM in a region between the first subpixel and the third subpixel at a side of the first color filter CF1 and at a first side CFS1 of the third color filter CF3.

A width of the overlap area between the black matrix BM and the third color filter CF3 in the first side CFS1 can be identical to a width of the overlap area between the black matrix BM and the third color filter CF3 in the second side CFS2. The width of the overlap area between the black matrix BM and the third color filter CF3 in each of the first side CFS1 and the second side CFS2 can be a second width.

The black matrix BM provided between the first subpixel SP1 and the third subpixel SP3 can include a thirteenth side BMS13 adjacent to the third subpixel SP1 and a fourteenth side BMS14 adjacent to the first subpixel SP1. A distance between an end of the thirteenth side BMS13 of the black matrix BM and an end of the first side CFS1 of the third color filter CF3 can be a thirteenth distance d13. A distance between an end of the fourteenth side BMS14 of the black matrix BM and an end of the first side CFS1 of the third color filter CF3 can be a fourteenth distance d14.

The thirteenth distance d13 can be greater than the fourteenth distance d14. That is, the end of the third color filter CF3 in the first side CFS1 can be disposed closer to the first subpixel SP1 than the third subpixel SP3. In this case, the thirteenth distance d13 can be the same as the third distance d3, but not necessarily. The thirteenth distance d13 can be different from the third distance d3. Also, the fourteenth distance d14 can be the same as the fourth distance d4, but not necessarily. The fourteenth distance d14 can be different from the fourth distance d4. In one embodiment of the present disclosure, the thirteenth distance d13 and the fourteenth distance d14 can have a ratio of 5:2.

The black matrix BM provided between the third subpixel SP3 and the fourth subpixel SP4 can include a fifteenth side BMS15 adjacent to the third subpixel SP1 and a sixteenth side BMS16 adjacent to the fourth subpixel SP4. A distance between an end of the fifteenth side BMS15 of the black matrix BM and an end of the second side CFS2 of the third color filter CF3 can be a fifteenth distance d15. A distance between an end of the sixteenth side BMS16 of the black matrix BM and an end of the second side CFS2 of the third color filter CF3 can be a sixteenth distance d16.

The fifteenth distance d15 can be greater than the sixteenth distance d16. That is, the end of the third color filter CF3 in the second side CFS2 can be disposed closer to the fourth subpixel SP4 than the third subpixel S3. In this case, the fifteenth distance d15 can be the same as the ninth distance d9, but not necessarily. The fifteenth distance d15 can be different from the ninth distance d9. Also, the sixteenth distance d16 can be the same as the tenth distance d10, but not necessarily. The sixteenth distance d16 can be different from the tenth distance d10. In one embodiment of the present disclosure, the fifteenth distance d15 and the sixteenth distance d16 can have a ratio of 5:2.

The display panel 110 according to one embodiment of the present disclosure is designed in that the overlap area between the third color filter CF3 and the black matrix BM is relatively large in the side adjacent to the subpixel. Thus, even though the process error occurs in the display panel 110 according to one embodiment of the present disclosure, the fourth color filter CF4 can be provided over the entire emission area EA, and it is possible to prevent the color loss from occurring in the third subpixel SP3.

The display panel 110 according to one embodiment of the present disclosure can be designed in that the overlap area between the third color filter CF3 and the black matrix BM can be relatively large in the side adjacent to the transmission area TA.

As shown in FIG. 10, the third color filter CF3 can further include a third side CFS3 facing the transmission area TA. The black matrix BM provided between the third subpixel SP3 and the transmission area TA can include a seventeenth side BMS17 adjacent to the third subpixel SP3 and an eighteenth side BMS18 adjacent to the transmission area TA. A distance between an end of the seventeenth side BMS17 of the black matrix BM and an end of the third side CFS3 of the third color filter CF3 can be a seventeenth distance d17. A distance between an end of the eighteenth side BMS18 of the black matrix BM and an end of the third side CFS3 of the third color filter CF3 can be an eighteenth distance d18.

The seventeenth distance d17 can be greater than the eighteenth distance d18. The seventeenth distance d17 can be the same as the fifth distance d5 and the eleventh distance d11, but not necessarily. The seventeenth distance d17 can be different from the fifth distance d5 and the eleventh distance d11. Also, the eighteenth distance d18 can be the same as the sixth distance d6 and the twelfth distance d12, but not necessarily. The eighteenth distance d18 can be different from the sixth distance d6 and the twelfth distance d12. In one embodiment of the present disclosure, the seventeenth distance d17 and the eighteenth distance d18 can have a ratio of 5:2.

The display panel 110 according to one embodiment of the present disclosure is designed in that the overlap area between the third color filter CF3 and the black matrix BM is relatively large in the side adjacent to the transmission area TA. Thus, even though the process error occurs, the third color filter CF3 can be provided over the entire third emission area EA3. Accordingly, the display panel 110 according to one embodiment of the present disclosure can prevent the color loss from occurring in the first subpixel SP1 and the fourth subpixel SP4.

The display panel 110 according to one embodiment of the present disclosure is designed in that the portion of the color filter CF is formed to be relatively small in the area adjacent to the white subpixel, thereby reducing the invasion of the color filter CF into the white subpixels. Accordingly, the display panel 110 according to one embodiment of the present disclosure can reduce an emission of light of a different color rather than white in the white subpixel.

Also, in the display panel 110 according to one embodiment of the present disclosure, the size of the color filter CF is relatively large in the area which is not adjacent to the white subpixel, whereby the color filter CF can be stably formed in the emission area EA. Accordingly, the display panel 110 according to one embodiment of the present disclosure can prevent the color loss from occurring in the subpixels other than the white subpixel. Furthermore, the display panel 110 according to one embodiment of the present disclosure can maintain high luminous efficiency even with low power and can reduce power consumption.

In the display panel 110 according to one embodiment of the present disclosure, a blue color filter is firstly deposited over a second substrate 112, and then a red color filter and a green color filter are deposited thereon. That is, in the display panel 110 according to one embodiment of the present disclosure, the blue color filter can be disposed between the black matrix BM and the red color filter or between the black matrix BM and the green color filter. In the display panel 110 according to one embodiment of the present disclosure, the color filter CF is relatively large in the area not adjacent to the white subpixel, so that the color filter CF can invade into the adjacent subpixel area due to the process error. In this case, the color invasion can occur in the color of the firstly stacked color filter. In the display panel 110 according to one embodiment of the present disclosure, the blue color filter with relatively low visibility is deposited earlier than the red color filter and the green color filter, so that it is possible to minimize visibility of the invaded color in case of color invasion.

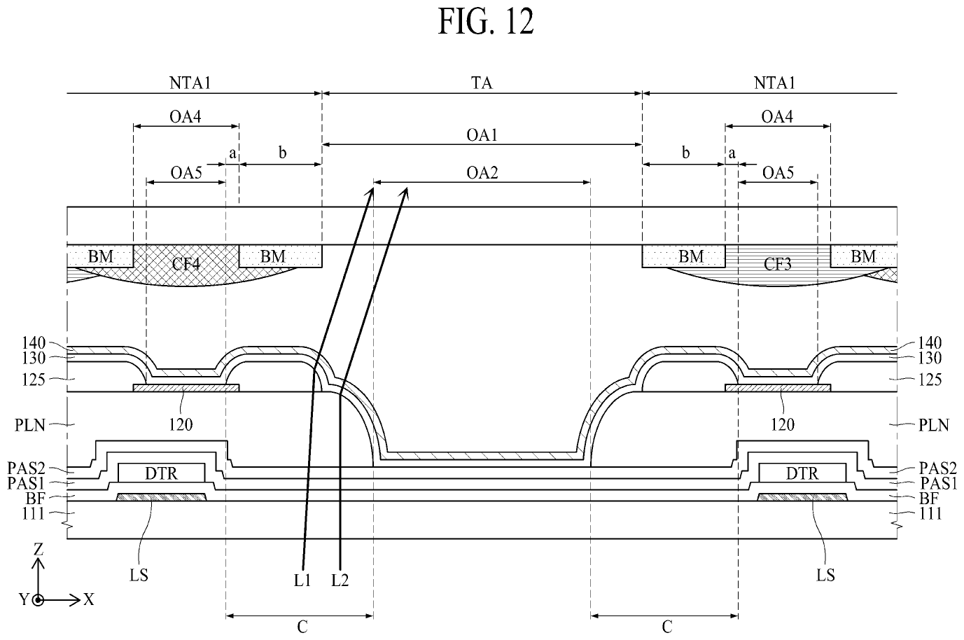

FIG. 11 is a cross sectional view illustrating an example of a black matrix, a bank, and a planarization layer according to one embodiment of the present disclosure, and FIG. 12 is a cross sectional view illustrating a comparative embodiment.

Referring to FIG. 11, in the display panel 110 according to one embodiment of the present disclosure, an end of a planarization layer PLN is not protruded from an end of a black matrix BM in a transmission area TA.

Specifically, the black matrix BM can include a first opening area OA1 provided in an area overlapped or aligned with the transmission area TA. The planarization layer PLN can include a second opening area OA2 provided in an area overlapped or aligned with the transmission area TA.

In the display panel 110 according to one embodiment of the present disclosure, the second opening area OA2 of the planarization layer PLN can be equal to or larger than the first opening area OA1 of the black matrix BM. Accordingly, the planarization layer PLN can be provided in such a way that its end exposed in the second opening area OA2 cannot protrude from an end of the black matrix BM exposed in the first opening area OA1.

Meanwhile, a bank 125 can include a third opening area OA3 provided in an area overlapped or aligned with the transmission area TA. In the display panel 110 according to one embodiment of the present disclosure, the third opening area OA3 of the bank 125 can be larger than the first opening area OA1 of the black matrix BM. Accordingly, the bank 125 can be provided in such a way that its end exposed in the third opening area OA3 can be provided inside a non-transmission area NTA than an end of the black matrix BM exposed in the first opening area OA1.

Also, the black matrix can further include a fourth opening area OA4 provided in an area overlapped with each of the plurality of subpixels SP1, SP2, SP3, and SP4. The bank 125 can further include a fifth opening area OA5 provided in an area overlapped with each of the plurality of subpixels SP1, SP2, SP3, and SP4. In this case, the fifth opening area OA5 of the bank 125 can be smaller than the fourth opening area OA4 of the black matrix BM.

There can be a first horizontal distance ‘a’ between the end of the bank 125 exposed in the fifth opening area OA5 and the end of the black matrix BM exposed in the fourth opening area OA4. There can be a second horizontal distance ‘b’ between the end of the black matrix BM exposed in the fourth opening area OA4 and the end of the black matrix BM exposed in the first opening area OA1. There can be a third horizontal distance ‘c’ between the end of the bank 125 exposed in the fifth opening area OA5 and the end of the planarization layer PLN exposed in the second opening area OA2. In one embodiment of the present disclosure, the third horizontal distance ‘c’ can be equal to the sum of the first horizontal distance ‘a’ and the second horizontal distance ‘b’.

That is, in the display panel 110 according to one embodiment of the present disclosure, the end of the planarization layer PLN exposed in the second opening area OA2 can coincide with the end of the black matrix BM exposed in the first opening area OA1 on the vertical line. That is, as shown in FIG. 11, the planarization layer PLN can be provided in such a way that its end exposed in the second opening area OA2 can coincide with the end of the black matrix BM exposed in the first opening area OA1 on the vertical line.

According to one embodiment of the present disclosure, the display panel 110 prevents the end of the planarization layer PLN exposed from the second opening area OA2 from protruding further than the end of the black matrix BM exposed in the first opening area OA1, thereby reducing external light from being refracted and transmitted from the side surface of the planarization layer PLN.

As shown in FIG. 12, the end of the planarization layer PLN exposed in the second opening area OA2 can protrude more than the end of the black matrix BM exposed in the first opening area OA1, such that OA2 is shorter than OA1. In this case, external light L2 incident on a lower surface of the first substrate 111 can be refracted from the side surface of the planarization layer PLN exposed in the second opening area OA2. Furthermore, since the side surface of the planarization layer PLN exposed in the second opening area OA2 has an inclined surface, the refraction angle of the planarization layer PLN can increase. The refracted external light L2 proceeds from the transmission area TA to the second substrate 112 and then passes through the second substrate 112 to reach a viewer. In this case, the display panel 110 can have a reduced haze and a reduced transparency due to the refracted external light L2.

In the display panel 110 according to one embodiment of the present disclosure, the end of the planarization layer PLN does not protrude more than the end of the black matrix BM, thereby minimizing the proceeding of the external light L2, which is refracted on the side surface of the planarization layer PLN, to the transmission area TA. In the display panel 110 according to one embodiment of the present disclosure, at least a portion of the external light L2 refracted on the side surface of the planarization layer PLN exposed in the second opening area OA2 can proceed to the black matrix BM. The external light L2 incident on the black matrix BM is absorbed in the black matrix BM and cannot proceed to the second substrate 112. Thus, the display panel 110 according to one embodiment of the present disclosure can reduce the external light L2 traveling to the transmission area TA after being refracted on the side surface of the planarization layer PLN.

Also, in the display panel 110 according to one embodiment of the present disclosure, the third opening area OA3 of the bank 125 is larger than the first opening area OA1 of the black matrix BM so that it is possible to reduce the external light being refracted on the side of the bank 125 and transmitted therethrough.

As shown in FIG. 12, in the display panel 110 according to one embodiment of the present disclosure, the third opening area OA3 of the bank 125 can have the same size as the first opening area OA1 of the black matrix BM. In this case, the external light L1 incident on the lower surface of the first substrate 111 can be refracted on the side surface of the bank 125 exposed in the third opening area OA3. Furthermore, since the bank 125 has the inclined surface in the side surface exposed in the third opening area OA3, the refraction angle of the bank 125 can increase. The refracted external light L1 proceeds from the transmission area TA to the second substrate 112 and passes through the second substrate 112 to reach a viewer. In this case, the display panel 110 can have a reduced haze and a reduced transparency due to the refracted external light L1.

In the display panel 110 according to one embodiment of the present disclosure, the end of the bank 125 is formed inside the non-transmission area NTA more than the end of the black matrix BM, thereby preventing the external light L1 refracted on the side surface of the bank 125 from proceeding to the transmission area TA. In the display panel 110 according to one embodiment of the present disclosure, most of the external light L1 refracted on the side surface of the bank 125 exposed in the third opening area OA3 can proceed to the black matrix BM. The external light L1 incident on the black matrix BM is absorbed in the black matrix BM and cannot proceed to the second substrate 112. Therefore, the display panel 110 according to one embodiment of the present disclosure can greatly reduce the external light L1 traveling to the transmission area TA after being refracted on the side surface of the bank 125.

According to one embodiment of the present disclosure, the display panel 110 minimizes the transmission of the external light L1 and L2, which is refracted by the bank 125 and the planarization layer PLN, to the transmission area TA, thereby preventing the haze from being degraded and improving transparency.

According to the present disclosure, the portion of the color filter overlapped with the black matrix is formed to be relatively small in the area adjacent to the white subpixel, thereby reducing the invasion of the color filter into the white subpixels. Therefore, the present disclosure can prevent the color invasion from occurring in the white subpixel.

Also, the portion of the color filter overlapped with the black matrix is formed to be relatively large in the area being not adjacent to the white subpixel, so that the color filter can be stably formed in the emission area. Accordingly, it is possible to prevent the color loss from occurring in the subpixels other than the white subpixel. Furthermore, it is possible to maintain the high luminous efficiency even with low power, and to reduce power consumption.

According to the present disclosure, it is possible to reduce the transmission of the external light, which is refracted by the bank and the planarization layer, to the transmission area, thereby preventing the haze from being degraded and improving transparency.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display device comprising:
a first substrate including a non-transmission area having a plurality of subpixels;
a second substrate arranged to face the first substrate;
a plurality of color filters arranged to respectively correspond to the plurality of subpixels over the second substrate; and
a black matrix disposed between each of the plurality of color filters over the second substrate, wherein each of the plurality of color filters is disposed to overlap at least a portion the black matrix, and the plurality of color filters has different areas overlapped with the black matrix according to positions of corresponding subpixels.

2. The display device according to claim 1,
wherein the plurality of subpixels includes a white subpixel, a first subpixel disposed adjacent to the white subpixel, and a second subpixel disposed not adjacent to the white subpixel,
the plurality of color filters includes a first color filter disposed to correspond to the first subpixel and a second color filter disposed to correspond to the second subpixel, and
the first color filter and the second color filter have different areas overlapped with the black matrix.

3. The display device according to claim 2,
wherein the first color filter includes a first side facing the white subpixel and a second side facing the second subpixel,
the first color filter overlaps the black matrix in a first area at the first side and overlaps the black matrix in a second area at the second side, and
a size of the second area is larger than that of the first area.

4. The display device according to claim 3, wherein the first color filter has a first end disposed in a center of the black matrix at the first side, and a second end of the first color filter is disposed closer to the second subpixel than the first subpixel at the second side.

5. The display device according to claim 2, wherein the second color filter includes a first side facing the first subpixel, and the second color filter has a first end disposed closer to a neighboring subpixel than the second subpixel at the first side.

6. The display device according to claim 2, wherein the plurality of color filters is not disposed at a position corresponding to the white subpixel.

7. The display device according to claim 1,
wherein the plurality of subpixels includes a first subpixel and a second subpixel disposed adjacent to each other,
the plurality of color filters includes a first color filter disposed to correspond to the first subpixel and a second color filter disposed to correspond to the second subpixel, and
the first color filter and the second color filter overlap each other over the black matrix.

8. The display device according to claim 7, wherein one of the first color filter and the second color filter is a blue color filter, and the blue color filter is disposed between the black matrix and the second color filter.

9. The display device according to claim 7, wherein an end of the first color filter is disposed closer to the second subpixel than the first subpixel, and the end of the second color filter is disposed closer to the first subpixel than the second subpixel.

10. The display device according to claim 7,
wherein the black matrix includes a first side adjacent to the first subpixel and a second side adjacent to the second subpixel, and
an end of the first side of the black matrix has a first distance from an end of the first color filter, and an end of the second side of the black matrix has a second distance from the end of the first color filter, wherein the second distance is less than the first distance.

11. The display device according to claim 10, wherein the first distance and the second distance have a ratio of 5:2.

12. The display device according to claim 1, further comprising:
a driving transistor provided over the first substrate; and
a planarization layer disposed over the driving transistor,
wherein the first substrate further includes a transmission area, and
the black matrix includes a first opening area provided in an area overlapped with the transmission area, and the planarization layer includes a second opening area provided in an area overlapped with the transmission area, and a size of the second opening area is equal to or larger than that of the first opening area.

13. The display device according to claim 12, wherein an end of the planarization layer exposed in the second opening area coincides with an end of the black matrix exposed in the first opening area on a vertical line.

14. The display device according to claim 12, further comprising:
a plurality of first electrodes provided in the plurality of subpixels over the planarization layer; and
a bank provided between each of the plurality of first electrodes, wherein the bank includes a third opening area provided in an area overlapped with the transmission area, and
a size of the third opening area is larger than that of the first opening area.

15. The display device according to claim 14,
wherein the black matrix includes a fourth opening area provided in an area overlapped with each of the plurality of subpixels, and the bank includes a fifth opening area provided in an area overlapped with each of the plurality of subpixels, and
a size of the fifth opening area is smaller than that of the fourth opening area.

16. The display device according to claim 15,
wherein an end of the bank exposed in the fifth opening area has a first horizontal distance from the end of the black matrix exposed in the fourth opening area, and the end of the black matrix exposed in the fourth opening area has a second horizontal distance from the end of the black matrix exposed in the first opening area,
the end of the bank exposed in the fifth opening area has a third horizontal distance from the end of the planarization layer exposed in the second opening area, and
the third horizontal distance is equal to a sum of the first horizontal distance and the second horizontal distance.

17. The display device according to claim 13, wherein the plurality of subpixels includes a white subpixel, and the black matrix is not provided between the white subpixel and the transmission area.

18. A display device comprising:
a first substrate and a second substrate facing the first substrate;
a first subpixel on the first substrate configured to emit light;
a first color filter on the second substrate corresponding to the first subpixel, wherein the first color filter is configured to receive light from the first subpixel and transmit light of a first color;
a second subpixel on the first substrate configured to emit light, wherein the second subpixel is configured to emit light of a second color;
a first portion of a black matrix in a region between the first subpixel and the second subpixel at a first side of the first color filter; and
a second portion of the black matrix at a second side opposite to the first side of the first color filter, wherein a width of the second side of the first color filter overlapping the second portion of the black matrix is larger than a width of the first side of the first color filter overlapping the first portion of the black matrix.

19. The display device of claim 18, wherein the second color is a white color, and wherein there is no color filter corresponding to the second subpixel or a transparent organic material is disposed on the second substrate corresponding to the second subpixel.

20. The display device of claim 18, further comprising:
a third subpixel on the first substrate configured to emit light;
a third color filter on the second substrate corresponding to the third subpixel, wherein the third color filter is configured to receive light from the third subpixel and transmit light of a third color;
a third portion of the black matrix in a region between the first subpixel and the third subpixel at a third side of the first color filter and at a first side of the third color filter,
wherein each of the first color filter and the third color filter is one of a red color filter, a blue color filter, or a green color filter.

21. The display device of claim 20, wherein the third color filter is the blue color filter, and wherein the first side of the third color filter is disposed on the third portion of the black matrix and the third side of the first color filter is disposed on the third color filter.

22. The display device of claim 18, further comprising a transmission area, the transmission area configured to allow externally incident light to transmit through the display device.

23. The display device of claim 22, the black matrix having a first opening area, the first opening area including a horizontal distance between a third portion of the black matrix and a fourth portion of the black matrix, and the first opening area is aligned with the transmission area.

24. The display device of claim 23, further comprising:
a planarization layer, the planarization layer having a second opening area, the second opening area including a horizontal distance between a first end of the planarization layer and a second end of the planarization layer; and
a bank, the bank having a third opening area, the third opening area including a horizontal distance between a first end of the bank and a second end of the bank.

25. The display device of claim 24, wherein the horizontal distance of the first opening area is same as the horizontal distance of the second opening area, and the horizontal distance of the third opening area is larger than the horizontal distance of the first opening area.

26. The display device of claim 24, wherein the horizontal distance of the second opening area is shorter than the horizontal distance of the first opening area, and the horizontal distance of the third opening area is same as the horizontal distance of the first opening area.
